(19) United States
(12) Patent Application Publication
(10) Pub. No.: US 2025/0385069 A1
(43) Pub. Date: Dec. 18, 2025

(54) MONITORING OF IMAGING PARAMETERS OF SCANNING ELECTRON MICROSCOPY

(71) Applicant: Carl Zeiss MultiSEM GmbH, Oberkochen (DE)

(72) Inventor: Stephan Nickell, Aalen (DE)

(21) Appl. No.: 19/316,064

(22) Filed: Sep. 2, 2025

Related U.S. Application Data
(63) Continuation of application No. PCT/EP2024/056457, filed on Mar. 12, 2024.

(30) Foreign Application Priority Data
Mar. 14, 2023 (DE) 10 2023 106 295.6

(51) Int. Cl. H01J 37/22; H01J 37/28

(52) U.S. Cl. CPC H01J 37/222; H01J 37/28; H01J 2237/1536; H01J 2237/2826

(57) ABSTRACT

Certain techniques allow for determining values of one or more imaging parameters that characterize in an imaging subsystem of a multi-beam scanning electron imaging system. For instance, a distortion model can be determined for each imaging subsystem. An optical transfer function can be determined for each imaging subsystem. For determining the values of the one or more imaging parameters, multiple pairs of test images are acquired that both depict certain structures of a sample.

### CROSS-REFERENCE TO RELATED APPLICATION

The present application is a continuation of, and claims benefit under 35 USC 120 to, international application No. PCT/EP2024/056457, filed Mar. 12, 2024, which claims benefit under 35 USC 119 of German Application No. 10 2023 106 295.6, filed Mar. 14, 2023. The entire disclosure of each of these applications is incorporated by reference herein.

### FIELD

Various examples of the disclosure generally relate to techniques of monitoring a multi-beam scanning electron imaging system. Various examples specifically relate to determining values of one or more imaging parameters characterizing imaging subsystems of the multi-beam scanning electron imaging system.

### BACKGROUND

Scanning Electron Microscopy (SEM) can provide large magnification and can be used to investigate, e.g., biological samples, semiconductor structures, or lithography masks.

Images acquired using SEM can exhibit distortions or other imaging artifacts. Distortions can be caused by the electron optics, stage drift, sample charging, or generally other imperfections of the scanning electron imaging system, e.g., of the control electronics.

Recently, multi-beam scanning electron imaging systems (MSEMs) have been employed to capture large-scale images of samples. Here, multiple images are acquired at different stage positions and the multiple images are stitched to form a composite image. Distortions can limit the possibility to stitched together multiple individual images to form the composite image. Distortions negatively affect the ability of montaging high-accuracy maps of large sample areas.

According to certain known techniques, a special calibration sample with distinct fiducials or features is routinely used for image distortion analysis routinely. An example is of this is disclosed in US 2021/0296089 A1. These calibration samples are manufactured at high precision. Accordingly, they are often expensive to manufacture and can be subject to wear-out.

Further, a calibration sample is usually mounted to a sample stage at a position that is offset from the position at which a sample under investigation is mounted. To calibrate, an imaging process used to obtain a high-accuracy map of the sample under investigation is interrupted and the stage is repositioned so that the calibration sample is in the field of view. Because the calibration sample is located at a position further away, the repositioning can take a significant amount of time. This interrupts and lengthens the imaging process.

The documents disclose techniques related to SEM: N. Marturi et al., Fast image drift compensation in scanning electron microscope using image registration, 2013 IEEE International Conference on Automation Science and Engineering (CASE), IEEE, 2013; P. Cizmar et al., Real-time scanning charged-particle microscope image composition with correction of drift, Microscopy and Microanalysis 17 (2011), S. 302-308; DE 10 2021 102 328 B3, and DE 10 2019 005 362 A1.

### SUMMARY

It desirable to provide advanced techniques of determining values of one or more imaging parameters that characterize a scanning electron imaging system. For example, it is desirable to quantify distortion in an MSEM.

Hereinafter examples are disclosed that involve acquiring pairs of test images, wherein each pair of test images includes a first test image and a second test image that depict identical structures of a sample. The first and second test images are acquired at different stage positions. Thereby, a certain structure is imaged using different beam paths of the electrons. Accordingly, the values of one or more imaging parameters can change in-between the two test images. For instance, distortions can be present that distort the appearance of the structure visible in both test images of a given pair. Using a comparison between the test images of a pair, the value of one or more imaging parameters can be determined. According to examples, upon the value of the one or more imaging parameters not fulfilling one or more predetermined desired properties, a correction is applied.

In an aspect, the disclosure provides a method of monitoring a multi-beam scanning electron imaging system is disclosed. The multi-beam scanning electron imaging system includes multiple imaging subsystems. The multiple imaging subsystems have fields of view that are arranged in a pattern. The method includes controlling a sample stage of the multi-beam scanning electron imaging system to load a sample to be imaged. The method also includes acquiring first test images at a first stage position of the sample stage using each of the multiple imaging subsystems and acquiring second test images at a second stage position of the sample states. The second stage position is different than the first stage position. Also, the second test images are acquired using each of the multiple imaging subsystems. The method also includes determining respective values of one or more imaging parameters for each of the multiple imaging subsystems. The one or more imaging parameters characterize the respective imaging subsystem. The values are determined based on a comparison between pairs of the first test images and the second test images that depict structures of the sample.

The first and second test images of each pair jointly depict certain respective structures of the sample. Certain structures are visible in each of the test images of a given pair. The appearance of the structures may vary, due to the impact of the one or more imaging parameters. Accordingly, by the comparison, the values of the one or more imaging parameters can be probed.

Program code that can be loaded and executed by a processor is disclosed. Execution of the program code by the processor causes the processor to perform the above-disclosed method of monitoring the multi-beam scanning electron imaging system.

A processing device includes a processor and a memory. The processor is configured to load program code from the memory and to execute the program code. Execution of the program code causes the processor to perform the above-identified method of monitoring the multi-beam scanning electron imaging system.

### BRIEF DESCRIPTION OF THE DRAWINGS

FIG. 1 schematically illustrates a MSEM according to various examples.

FIG. 2 schematically illustrates multiple fields of view of imaging subsystems of the MSEM according to various examples.

FIG. 3 is a flowchart of a method of monitoring and controlling an MSEM according to various examples.

FIG. 4 schematically illustrates stage offsets between different stage positions of a sample stage of the MSEM according to various examples.

FIG. 5 schematically illustrates an arrangement of structures of a sample with respect to multiple fields of view depending on the stage position according to various examples.

FIG. 6 schematically illustrates the arrangement of multiple structures of a sample with respect to fields of view of the MSEM according to various examples.

FIG. 7 schematically illustrates a dependency of a distortion value on a position within a field of view according to various examples.

FIG. 8 shows pseudocode for determining values of parameters of linear image shift distortion models according to various examples.

FIG. 9 schematically illustrates a correlation between multiple images according to various examples.

### DETAILED DESCRIPTION

Hereinafter, techniques will be disclosed pertaining to characterization of a scanning electron imaging system. Specifically, an MSEM can be characterized. An MSEM includes multiple imaging subsets, each providing a respective field of view (FOV). The FOVs are then combined to an aggregated FOV. According to various examples, the multiple imaging subsystems are characterized.

According to various examples, values of one or more imaging parameters characterizing a respective imaging subsystem of the MSEM are determined. In general, different imaging parameters can be characterized, including but not limited to: distortion; optical transfer function; scale factor. A distortion model can be determined for each of multiple imaging subsystems of the MSEM.

Generally, the distortion associated with an imaging subsystem describes a deviation from a rectilinear projection of the sample to the respective image acquired using that imaging subsystem. Different types of distortion can exist including linear distortion, radial distortion, barrel distortion, etc.

In general, the optical transfer function describes how different spatial frequencies in the sample are captured or transmitted in the respective image acquired using an associated imaging subsystem.

The scale factor describes a magnification level with which the sample is imaged. The magnification level can vary within each field of view of each imaging subsystem; and/or can vary from imaging subsystem to imaging subsystem.

A first type of the imaging parameters that can be characterized in the various disclosed examples has values that vary within each of the multiple FOVs associated with the multiple imaging subsystems of the MSEM. In other words, such first type of imaging parameter shows a dependency on the position within each of the individual FOVs of the imaging subsystems. An intra-FOV variation is observed.

A second type of the imaging parameters has values that are globally associated with each of the imaging subsystems but still vary from imaging subsystem to imaging subsystem. Thus, and inter-FOV variation is observed. According to the disclosed techniques, it is possible to characterize both types of imaging parameters. Furthermore, it is possible to characterize imaging parameters that exhibit, both, intra-FOV as well as inter-FOV variations.

It is possible (but not necessary) to apply corrections based on the values of the one or more imaging parameters. According to various examples, it is possible to apply one or corrections to an imaging process used to image the sample; these one or more corrections are based on the values of the one or more imaging parameters as previously determined. For instance, digital post-processing correction can be applied to measurement images that are acquired. Alternatively or additionally, it is also possible to apply hardware corrections to the imaging hardware of the multiple imaging subsystems. For this purpose, special-purpose corrective elements can be available. Control values of control signals provided to one or more electric or magnetic optical elements can be adjusted based on the values of the one or more imaging parameters as previously determined.

Thus, the same sample that is subject to the imaging process can be used for determining values of one or more imaging parameters. Accordingly, a self-calibration is enabled. A separate sample for calibration, i.e., a calibration sample, is not necessarily involved. This speeds up the imaging process and, furthermore, allows for a greater quality of the imaging process, especially when long data acquisition runs, i.e. over hours or days are involved.

Techniques are disclosed that enable to determine values of one or more imaging parameters-specifically, distortion-using image shift pairs acquired on a sample. In-between the acquisition of images of an image pair, it is considered that sample contamination and sample charging does not significantly change. I.e., any differences in the test images of an image pair are due to varying imaging parameters (rather than due to sample contamination or charging). Furthermore, it is considered that imaging settings are constant and do not change in-between the acquisition of multiple test images of a test image pair. I.e., for instance, the dwell time, focus and electron optics nominal settings are not changed. Then, such imaging settings do not affect varying appearances of structures in the two test images of a given pair.

For above-described measurement procedure, an a-priori unknown sample can be employed. It would also be possible to employ an a-priori known sample, i.e., a calibration sample. The calibration sample can include known structures, e.g., having known shape and/or size. According to the disclosed techniques, any arbitrary sample can be employed for respective measurements, e.g., having unique, random structures. Information can be acquired across the entire FOV of each imaging subsystem and used for determining the values of the one or more imaging parameters. I.e., the values of the one or more imaging parameters are not determined on certain isolated features or fiducial patterns of a calibration sample, but can rather be determined based on the full FOV. This renders the method more robust and less stringent on the desired test sample properties such as homogeneity.

According to various examples, one or more values of a distortion model are determined. For example, a linear distortion model can be used. Here, orthogonal imaging directions—i.e., X-direction and Y-direction—can be quantified by a respective translational shift along X- or Y-direction that varies linearly as a function of the position within the respective FOV. I.e., the distortion model includes a first linear image shift along a first imaging direction and a second linear image shift along a second imaging direction.

It is, for example, possible that the distortion model is limited to such first linear image shift and second linear image shift, i.e., consists of the first linear image shift and the second linear image shift, i.e., nonlinear shifts, rotations, radial distortions, etc. can be excluded. Such techniques are based on the finding that, often, a distortion model consisting of linear image shifts along orthogonal imaging directions captures most prominent distortion imaging artifacts in a robust manner. Higher-order distortion imaging artifacts may not be involved to obtain a sufficiently accurate image of a sample. Thus, restricting the distortion model to two orthogonal linear image shifts can enable a fast and robust correction of respective distortion imaging artifacts.

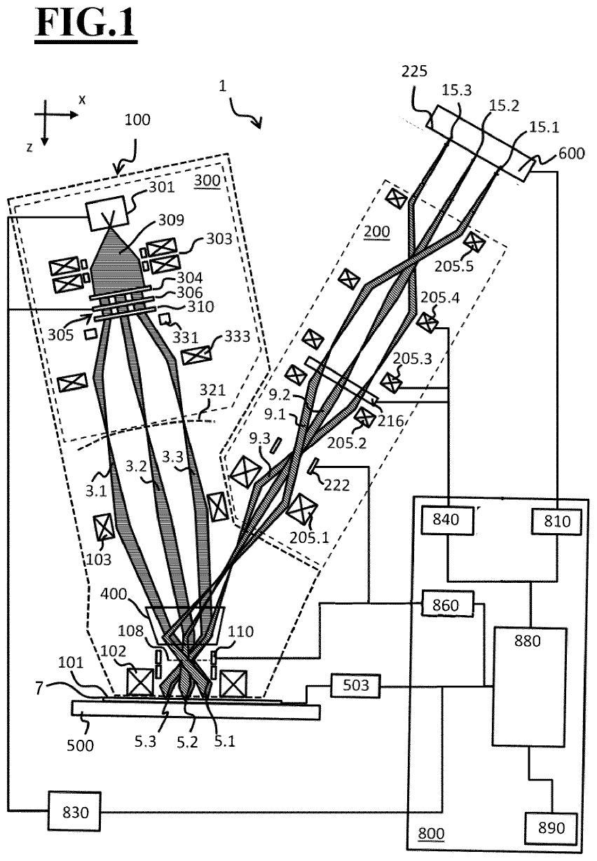

FIG. 1 is a schematic illustration of an MSEM 1. Further information relating to such MSEMs and components used therein, such as, for instance, particle sources, multi-aperture plate and lenses, can be obtained from the international patent applications WO 2005/024881, WO 2007/028595, WO 2007/028596, WO 2011/124352 and WO 2007/060017 and the German patent applications having the publication numbers DE 10 2013 016 113 A1 and DE 10 2013 014 976 A1, the disclosure of which in the full scope thereof is incorporated by reference in the present application.

The MSEM 1 uses a plurality of charged particle beams for forming an image of an sample 7. The MSEM 1 generates a plurality of J primary beamlets 3.1, 3.2, 3.3 which strike the sample 7 to generate interaction products, e.g., secondary electrons, which emanate from the sample 7, form secondary beamlets 9.1, 9.2, 9.3, and are subsequently detected.

Each one of the primary and secondary beamlets 3.1, 3.2, 3.3, 9.1, 9.2, 9.3 is formed and guided by a respective imaging subsystem of the MSEM 1. Each imaging subsystem is associated with a respective FOV. Images acquired by a respective imaging subsystem have a respective FOV.

The primary beamlets 3.1, 3.2, 3.3 are formed by electrons which are incident on a surface of the sample 7 at a plurality of locations and generate a plurality of primary electron beam focus spots 5.1 5.2, 5.3 that are spatially separated from one another.

The sample 7 to be examined can be of any desired type, e.g., a semiconductor wafer or a semiconductor mask, and can comprise an arrangement of miniaturized elements.

The surface of the sample 7 is arranged in a sample plane 101 of an objective lens system 102 of a first particle optical unit 100 (also referred to as illumination system).

A diameter of the minimal beam spots or focus spots 5.1 5.2, 5.3 shaped in the sample plane 101 can be small. Exemplary values of this diameter are below four nanometers, for example three nm or less. The focusing of the primary beamlets 3.1, 3.2, 3.3 for shaping the focus spots 5.1 5.2, 5.3 is carried out by the objective lens system 102. In this case, the objective lens system 102 can comprise a magnetic immersion lens. Further examples of focusing mechanisms are described in the German patent DE 102020125534 B3, the entire content of which is herewith incorporated in the disclosure.

The plurality of focus spots 5.1 5.2, 5.3 of the primary beamlets form a pattern in the sample plane 101.

The number J of primary beamlets 3.1, 3.2 and 3.3 may be five, 25, 90 to 100, or more (for sake of simplicity, only three primary beamlets 3.1, 3.2 and 3.3 with corresponding focus points 5.1, 5.2 and 5.3 are shown in FIG. 1).

In practice, the number of beamlets J, and hence the number of incidence locations or focus spots 5.1 5.2, 5.3, can be chosen to be significantly greater, such as, for example, J=10×10, J=20×30 or J=100×100. Exemplary values of the pitch between the incidence locations are 1 micrometer, 10 micrometers, or more, for example 40 micrometers.

The number of primary and secondary beamlets J defines the number of FOVs. Each imaging subsystem has a respective FOV. The respective FOV is defined by scanning the respective pair of primary and secondary beamlets (e.g., beamlets 3.1 and 9.1) over the sample 7 in the respective FOV.

The primary beamlets 3.1, 3.2, 3.3 striking the sample 7 generate interaction products, e.g., secondary electrons, back-scattered electrons, which emanate from the surface of the sample 7, or primary particles that have experienced a reversal of movement for other reasons. The interaction products emanating from the surface of the sample 7 are shaped by the objective lens system 102 to form the secondary beamlets 9.1, 9.2, 9.3. Secondary electrons included in the secondary beamlets 9.1, 9.2, 9.3 are used for imaging.

The MSEM 1 provides a detection beam path for guiding the plurality of secondary beamlets 9.1, 9.2, 9.3 to a secondary electron imaging system 200. The secondary electron imaging system 200 includes several electron-optical lenses 205.1 to 205.5 for directing the secondary beamlets 9.1, 9.2, 9.3 towards a spatially resolving detector system 600.

The imaging with the secondary electron imaging system 200 is strongly magnifying such that both the pattern of the primary beamlets on the wafer surface and the size and shape of focal points of the primary beamlets are imaged in much magnified fashion. By way of example, a scale factor/magnification is between 100× and 300× such that one nm on the wafer surface is imaged enlarged to between 100 nm and 300 nm. In an example, an image field of a multi-beam device with for example 100 μm diameter is enlarged to approximately 30 mm.

The primary beamlets 3.1, 3.2, 3.3 are generated in a beam generation apparatus 300 comprising at least one particle source 301 (e.g., an electron source), at least one collimation lens 303, a multi-aperture arrangement 305 and a first field lens 331 and a second field lens 333. The particle source 301 generates at least one diverging particle beam 309, which is at least substantially collimated by the at least one collimation lens 303, and which illuminates the multi-aperture arrangement 305. The multi-aperture arrangement 305 includes an aperture plate 304 (also referred to as filter plate or multi-hole aperture plate), which has a plurality of J openings formed therein in a first raster arrangement. Particles of the illuminating particle beam 309 pass through the J apertures or openings of the first aperture plate 304 and form the plurality J of primary beamlets 3.1, 3.2, 3.3. Particles of the illuminating particle beam 309 which strike the first aperture plate 304 are absorbed by the latter and do not contribute to the formation of the primary beamlets 3.1, 3.2, 3.3. A multi-aperture arrangement 305 usually has at least a further multi-aperture plate 306, for example a lens array, a stigmator array, or an array of deflection elements.

Together with the field lens 331 and a second field lens 333, the multi-aperture arrangement 305 focuses each of the primary beamlets 3.1, 3.2, 3.3 in such a way that focal points are formed in an intermediate image surface 321. Alternatively, the beam foci and the intermediate image surface 321 can be virtual. The intermediate image surface 321 can be curved to pre-compensate a field curvature of the imaging system arranged downstream of the intermediate image surface 321.

The at least one field lens 103 and the objective lens system 102 provide a first imaging particle optical unit for imaging the surface 321, in which the beam foci are formed, onto the sample plane 101 such that a second pattern of focus spots 5.1 5.2, 5.3 of the primary beamlets 3.1, 3.2, 3.3 is formed there. Typically, the surface 25 of the sample 7 is arranged in the sample plane 101, and the focal spots 5.1 5.2, 5.3 are correspondingly formed on the object surface 25. The plurality of primary beamlets 3.1, 3.2, 3.3 form a crossover point 108, in the vicinity of which a first deflection scanner 110 is arranged. The first deflection scanner 110 is used to deflect the plurality of primary beamlets 3.1, 3.2, 3.3 collectively and synchronously such that the plurality of focus spots 5.1 5.2, 5.3 are moved simultaneously over the surface 25 of the sample 7. Raster scanning is implemented, thereby imaging the sample 7. The first deflection scanner 110 is driven by a scanning control unit 860 such that in an inspection mode of operation, a plurality of two-dimensional image data of the surface is acquired. Additionally, the MSEM 1 can include further static deflectors configured to adjust the position of the plurality of the primary beamlets 3.1, 3.2, 3.3.

The objective lens system 102 and the projection lenses 205 provide a secondary electron imaging system 200 for imaging the sample plane 101 onto an imaging plane 225. The objective lens system 102 is thus a lens or a lens system that is part of both the first and the second particle optical unit, while the field lenses 103, 331 and 333 belong only to the first particle optical unit 100, and the projection lenses 205 belongs only to the secondary electron imaging system 200.

A beam divider 400 is arranged in the beam path of the first particle optical unit 100 between the field lens 103 and the objective lens system 102. The beam divider 400 is also part of the second optical unit in the beam path between the objective lens system 102 and the projection lenses 205.

The first deflection scanner 110 is arranged in a primary electron beam path or in a joint electron beam path. In the example shown in FIG. 1, the secondary beamlets 9.1, 9.2, 9.3 transmit during use the first deflection scanner 110 in opposite direction and the scanning movement of the secondary beamlets 9.1, 9.2, 9.3 is partially compensated. The secondary electrons have typically a different kinetic energy compared to the primary electrons. Therefore, the scanning movement of the moving irradiation positions is only partially compensated. To fully compensate the scanning movement of the secondary beamlets 9.1, 9.2, 9.3, the collective beam deflector 222 is arranged in the secondary electron beam path.

The secondary electron imaging system 200 includes the second, collective beam deflector 222 which is arranged in the vicinity of a crossover point of the secondary beamlets 9.1, 9.2, 9.3. The second, collective beam deflector 222 is operated synchronously with the first deflection scanner 110 and compensates during use a beam deflection of the secondary beamlets 9.1, 9.2, 9.3 such that centers 15 of the beamlets 9 remain at constant position on the imaging plane 225. Thereby, each secondary beamlet 9 is kept within the area of a set of detection elements, which is assigned to the individual secondary beamlet 9.

The secondary electron imaging system 200 includes electron-optical lenses 205.1 to 205.5 to adjust a focus plane of the secondary beamlets 9.1, 9.2, 9.3. A defocus can be applied. The electron-optical lenses 205.1 to 205.5 can thus implement corrective elements to correct the focus plane. The electron-optical lenses 205.1 to 205.5 are shown as magneto-optical elements but are not limited to magneto-optical elements and can comprise also electro-static lens elements or stigmators. With the electron-optical lenses 205.1 to 205.5, the secondary beamlets 9.1, 9.2, 9.3 can be focused into the imaging plane 225 of the secondary electron imaging system 200.

The secondary electron imaging system 200 can include a plurality of further corrective elements, for example at least one of a multi-aperture array element, a deflector or an exchangeable aperture stop. Together with the objective lens system 102, the lenses serve to focus the secondary beamlets 9.1, 9.2, 9.3 on the spatially resolving detector system 600 and, in the process, allow to correct or compensate the magnification and rotation of the pattern of the secondary beamlets 9.1, 9.2, 9.3 in the imaging plane 225. Thereby, the pattern of the plurality of secondary beamlets 9.1, 9.2, 9.3 can stabilized. For example, a first and second magnetic lenses 205.4 and 205.5 (as further examples of corrective elements) are designed in reversed order to one another and have oppositely directed magnetic fields. A Larmor rotation of the secondary beamlets 9.1, 9.2, 9.3 can be compensated by suitably applying control signals to (driving) the magnetic lenses 205.4 and 205.5. The secondary electron imaging system 200—in the illustrated example—includes further corrective elements, specifically a multi-aperture plate 216.

The MSEM 1 furthermore includes a control system 800 configured both for controlling the individual particle optical components of the multiple particle beam system and for evaluating and analyzing the signals obtained by the detector system 600. For example, the control system 800 can be configured to acquire pairs of test images and then evaluate the test images to determine values of one or more imaging parameters. In this case, the control or controller system 800 can be constructed from a plurality of individual electronic computers or electronic components. By way of example, the control system 800 includes a control processor 880, a control module 840 for the control of the electro-optical elements of the secondary electron imaging system 200, and a control module 830 for the control of the electro-optical elements of the primary beamlet generation unit. The control system 800 is further connected to a control module 503 for supplying a voltage to the sample 7, the voltage also being referred to as extraction voltage. Thereby, during use, an extraction field is generated between the objective lens system 102 and the surface 25 of the sample 7. During use, the extraction field decelerates the primary charged particles of the primary beamlets 3.1, 3.2, 3.3 before the object surface 25 is reached and generates an additional focusing effect on the plurality of primary beamlets 3.1, 3.2, 3.3. At the same time, the extraction field serves during use to accelerate the secondary particles out of the surface 25 of the sample 7.

Further, the control system 800 includes the scanning control unit 860 for the raster scanning.

The detector system 600 includes a plurality of sets of detection elements with one set of detection elements for each secondary beamlet 9. During use, each set of detection elements is configured to record the intensity signal of the assigned secondary beamlet 9. The plurality of intensity signals for the plurality of secondary beamlets 9.1, 9.2, 9.3 is transferred to the image data acquisition unit 810, where the image data is processed and stored in memory 890. Accordingly, multiple images are acquired, one for each imaging subsystem. These multiple images can be combined to an aggregated image having an aggregated FOV.

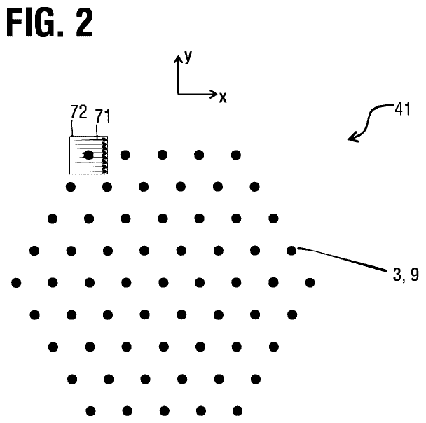

As explained above, the MSEM 1 includes a mechanism for generating multiple primary beamlets 3.1, 3.2, 3.3 which are arranged in a pattern. This pattern is matched to the apertures of the aperture plate 304 and defines the arrangement of the FOVs. An example is illustrated in FIG. 2.

FIG. 2 illustrates the arrangement of the primary beamlets 3 and the secondary beamlets 9 in the sample plane. A respective pattern 41 is illustrated. Each of the primary and secondary beamlets 3, 9 is scanned—e.g., using scan lines 71—so that a respective FOV 72 is illustrated (the FOV 72 is only illustrated for a single pair of primary and secondary beamlets 3, 9 in the example of FIG. 2).

In the image processing, images of each of the FOVs 72 are then combined to form an aggregated image. The aggregated image can be formed without stage moving.

It is possible to combine multiple such aggregated images by stitching, i.e., alternatingly acquiring aggregated images and moving the stage to a new stage position.

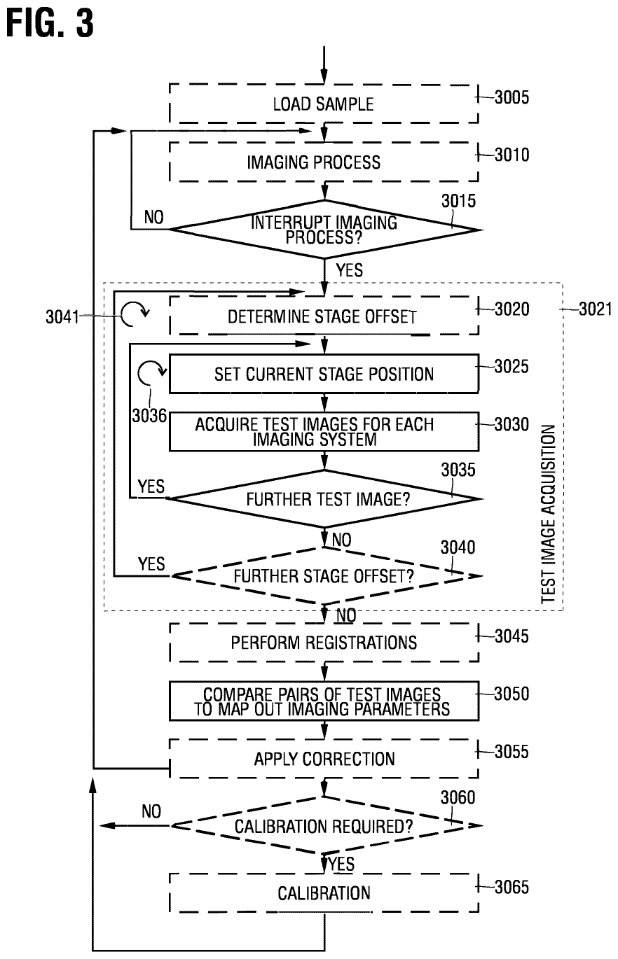

FIG. 3 is a flowchart of a method according to various examples. The method of FIG. 3 is computer-implemented. The method of FIG. 3 can be executed by a processor upon loading program code from a memory and upon executing the program code.

The method of FIG. 3 generally relates to characterizing a MSEM. Values of one or more imaging parameters of the MSEM are determined. The method of FIG. 3 can also include correcting deviations of the values from a norm.

Optional boxes are shown with dashed lines.

At box 3005, the MSEM is controlled to load a sample. Box 3005 can include evacuating a loading lock; moving the sample stage to an imaging position; activating imaging subsystems; etc.

While in the illustrated example of FIG. 3 a sample is loaded, in other scenarios the sample can also be pre-loaded, i.e., already be present in the MSEM imaging chamber. As such, box 3005 is optional. The sample can be a wafer. The sample can include one or more semiconductor devices such as transistors or memory units. The sample can be a lithography mask. The sample can include organic structures. The sample can include a-priori unknown structures.

In some examples, the sample is a calibration sample. Here, shape and size and/or relative arrangement of reference structures/fiducials of the calibration sample are a priori known at great accuracy so as to enable detection of deviations against this prior knowledge.

At box 3010, an imaging process is optionally executed. Here, multiple images of the sample are acquired at multiple stage position. In further detail, each of multiple imaging subsystems of the MSEM is controlled to contemporaneously acquire a sequence of images at a plurality of stage positions of the sample stage. Thereby, the sample is imaged. Stitching of the multiple images perform an aggregated image is possible.

At box 3015, it can be determined whether the imaging process is to be interrupted. The imaging process is interrupted responsive to one or more trigger criteria. Such trigger criteria can be, e.g.: expiry of a timer; detection that one or more control values of control electronics of at least one of the imaging subsystems are outside of a predefined range; etc.

In other words, a long-term imaging process can be interrupted from time to time to check whether values of one or more imaging parameters fulfill desired certain properties. Thereby, the quality of the imaging process can be ensured, even for comparatively long imaging processes where drift of imaging parameter values is to be expected. For instance, long-term imaging processes can take durations of more than an hour or more than 10 hours or even days. Such long-term imaging processes are typically used to obtain sufficient amount of measurement images to map out a sample in a large region, e.g., having side lengths of not less than a millimeter. Also, a time evolution of a sample structure can be observed by long-term measurements.

The imaging process can be interrupted at box 3015 to acquire test images. Based on these test images, it is the later on possible to determine values of one or more imaging parameters of the imaging subsystems.

If the imaging process is interrupted at box 3015, the method commences at box 3020. This is part of a test image acquisition process highlighted by box 3021.

At box 3020, a certain stage offset is determined (i.e., set). Instead of flexibly determining the stage offset at box 3020, the stage offset may also be fixedly predetermined. As such, box 3020 is optional.

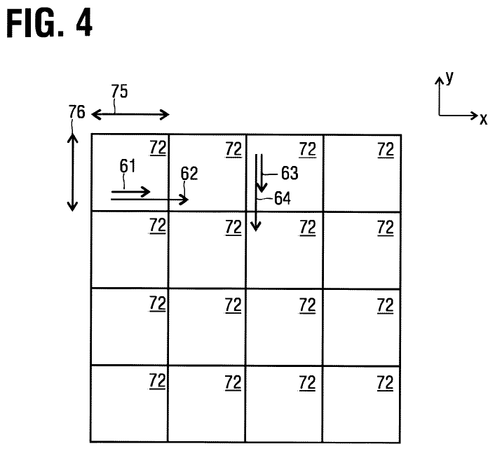

The stage offset specifies an offset between two sample stage positions for which respective test images forming an image pair are acquired. It is possible that the stage offset between these stage positions is set depending on the particular imaging parameter or imaging parameters for which values are to be determined, i.e., it is possible that the stage offset is determined depending on the particular imaging parameter to be monitored. Thus, in other words, it is possible that for different imaging parameters different stage offsets are determined. For instance, a smaller stage offset can be chosen when determining values of a distortion model if compared to the stage offset that is used when determining inter-FOV changes of the optical transfer function, to give only one example. More generally, it would be possible to determine different stage offsets depending on whether an inter-FOV or intra-FOV type of imaging parameter is to be characterized. Further details are illustrated in connection with FIG. 4.

Aspects with respect to the stage offset are illustrated in connection with FIG. 4. FIG. 4 illustrates a pattern of the multiple FOVs 72 associated with each imaging subsystem of the MSEM. (Typically, the FOVs 72 overlap; this overlap is omitted from FIG. 4, for sake of simplicity).

The FOVs 72 have a certain side length 75 along the X-direction and a side length 76 along the Y-direction. While the FOVs 72 in the illustrated example of FIG. 4 have a square shape, they can also have other shapes.

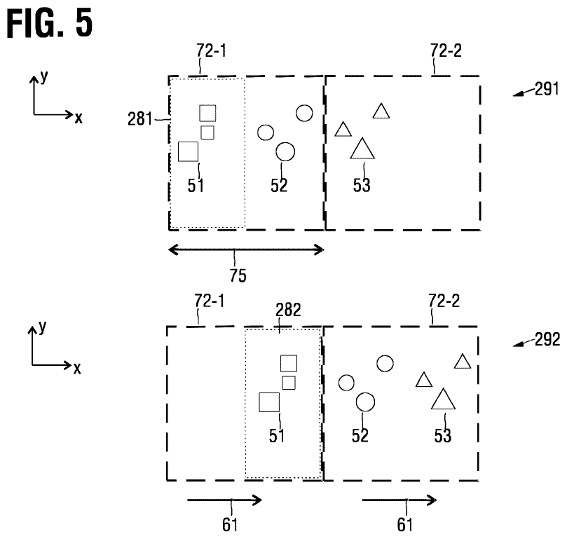

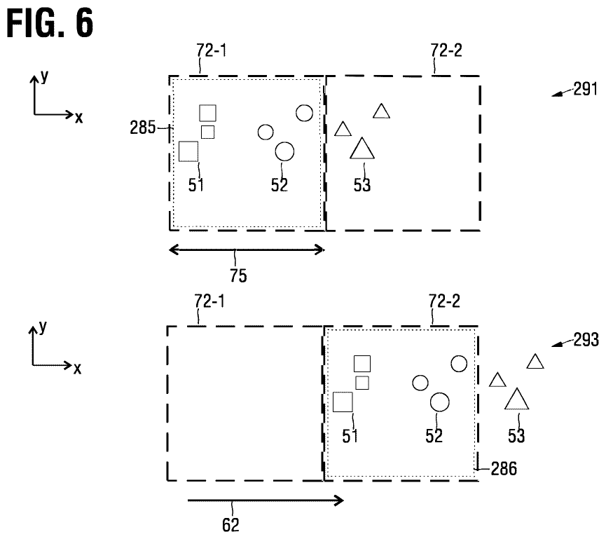

In a first example, the stage offset 61 along the X direction is determined to be roughly 50% of the side length 75; similarly, the stage offset 63 is determined to be roughly 50% of the respective side length 76 along the Y direction. More generally, it would be possible that the stage offset is determined to be smaller than 60% of the respective side lengths 75, 76. Such an offset 61, 63 that is significantly smaller than the side lengths 75, 76 of the FOVs 72 enables to determine intra-FOV variations of a value of an imaging parameter. For instance, the intra-FOV variation of the distortion can be determined. This is because by such dimensioning of the stage offset 61, 63, partial images acquired using each imaging subsystem associated with the FOVs depict the same structure; the structure does not move out of the FOV. Such a scenario is illustrated in FIG. 5. In FIG. 5, top, two adjacent FOVs 72-1, 72-2 and corresponding structures 51, 52, 53 are illustrated, for a first stage position 291. Then, the stage offset 61 is applied by re-positioning the stage to a new stage position 292. As illustrated in FIG. 5, bottom, the structure 51 moves from the left edge of the FOV 72-1 to the right edge of the FOV 72-1. Similarly, the structure 53 moves from the left edge of the FOV 72-2 to the right edge of the FOV 72-2. This is different for a second example. In a second example, the stage offset 62 (cf. FIG. 4) along the X direction is determined to be roughly 100% of the side length 75; similarly, the stage offset 64 is determined to be roughly 100% of the respective side length 76 along the Y direction. More generally, it is possible that the stage offset is determined to be larger than 60% of the respective side length 75, 76. Such a scenario is illustrated in FIG. 6. Here, FIG. 6, top (again, as in FIG. 5 top) illustrates the position of the structures 51-53 at a first stage position 291; in FIG. 6, bottom illustrates the position of the structures 51-53 at another stage position 293 that is offset by the stage offset 62 amounting to the side length 75 of the FOVs 72-1, 72-2 from the first stage position 291. As illustrated, the structures 51, 52 move from certain positions within the FOV 72-1 into corresponding positions in the FOV 72-2. Such dimensioning of the stage offset 62, 64 is helpful for determining inter-FOV variations of a value of an imaging parameter. This is because a certain structure that is, for a first test image, located in a first FOV of a first imaging subsystem then moves out of this first FOV into a second FOV that is neighboring and is associated with a second imaging subsystem. Thereby, changes in the appearance of such structure are associated with different values of such imaging parameter for the two imaging subsystems.

While FIG. 4, FIG. 5, and FIG. 6 illustrate stage shifts along X direction, as well as along Y direction, in general, it is possible to employ stage shifts only along a single imaging direction, as well.

Referring again to FIG. 3: at box 3025, the sample stage is controlled to take a first stage position. Then, at box 3030, multiple test images are contemporaneously acquired using each of the multiple imaging subsystems. Each of the multiple test images covers at least a fraction respective FOV 72, as previously discussed in connection with FIG. 2 and FIG. 4. These multiple test images are acquired at the stage position set at box 3025.

Subsequently, at box 3035, it is determined whether a further test image is desired. If yes, and iteration 3036 is executed and a new stage position is set at the further iteration 3036 of box 3025. The new stage position is offset based on the stage offset determined at box 3020 from the stage position at the preceding iteration 3036.

For example, a pair of test images 281, 282 is illustrated in connection with the stage positions 291, 292 in the previously discussed scenario of FIG. 5. As illustrated, each of the test images 281, 282 covers a respective fraction of the FOV 72-1. The pair of test images 281, 282 is determined so that the structures 51 are at corresponding positions within each of the test images 281, 282. This is also illustrated for the scenario of FIG. 6, here for the pair of test images 285, 286. In the scenario of FIG. 6, each of the test images 285, 286 covers the respective entire FOV 72-1, 72-2; accordingly, the structures 51, 52 are arranged in corresponding positions of each of the test images 285, 286.

In the scenarios of FIG. 5 in FIG. 6, a single pair of test images is illustrated for the respective pair of stage positions 291, 292 as well as 291, 293. Respective pairs of test images can be formed at these stage positions for each or multiple of the FOVs of the MSEM. Using these test images that are offset along the X direction, the respective distortion can be probed along the X direction.

In some scenarios, two pairs of test images are acquired, wherein each pair of test images is associated with a respective stage offset along perpendicular imaging directions, e.g., X direction and why direction.

If, at box 3035, it is determined that further test images given the current stage offset setting are not required, then the method commences at box 3040. Here, a further iteration 3041 can be executed with a different stage offset. This can be helpful where different types of imaging parameters are to be characterized using different stage offset settings.

At optional box 3045, once all test images have been acquired, registrations are determined between pairs of test images acquired at multiple iterations 3036. In other words, pairs of first and second test images associated with different iterations 3036 are formed and then a registration between the first and second test images of these pairs are determined. For example, a registration between the test image 281 and the test image 282 can be performed (cf. FIG. 5). For example, a registration between the test image 285 and the test image 286 (cf. FIG. 6) can be performed.

In general, the registration maps pixels in the respective first test image to pixels in the respective second test image. The registration can be based on correspondences of the depicted pixels or features in the first and second test images. According to examples, the registration can provide a mapping between the entirety of the respective first test image and the entirety of the respective second test image. I.e., the entire extent of the first and second test images can be covered by the registration. This then enables a comparison between the respective first and second test images to be executed continuously across the entire test images, e.g., on a pixel-by-pixel level; this is in contrast to comparisons between test images that depict isolated calibration structures, such as local fiducials or markers. Here, only certain subregions of each test image are used for determining respective values of imaging parameters; accordingly, a spatial resolution with which values of imaging parameters are determined is comparatively lower for such prior art solutions that employ calibration samples.

The comparison between the test images is explained in further detail below.

Next, referring to FIG. 3, at box 3050, comparison between test images acquired at different stage positions are performed. Pairs of first and second test images that depict the same structure (as explained previously in connection with FIG. 5 and FIG. 6) are formed and compared with each other.

It is possible that the pairs of test images only cover a fraction of the entire field of view of the respective imaging subsystem (such a scenario is explained above in connection with FIG. 5). Here, prior to the comparison, it would be possible to crop parts of the acquired images that are depicting different structures not subject to the comparison.

Such cropping can be based on the registration, e.g., for regions of the image where low coincidence values are obtained from the registration. For instance, referring to FIG. 5, the image acquired using the imaging subsystem in the field of view 72-1 also depicts the structures 52 in the stage position 291; the respective part can be cropped so that the test image 281 is obtained.

It is possible that the comparison is pixel-by-pixel. I.e., a comparison value can be determined for each pixel of the test images of the respective pair. Such a scenario is, for example, possible where a continuous registration is provided across the entirety of the test images.

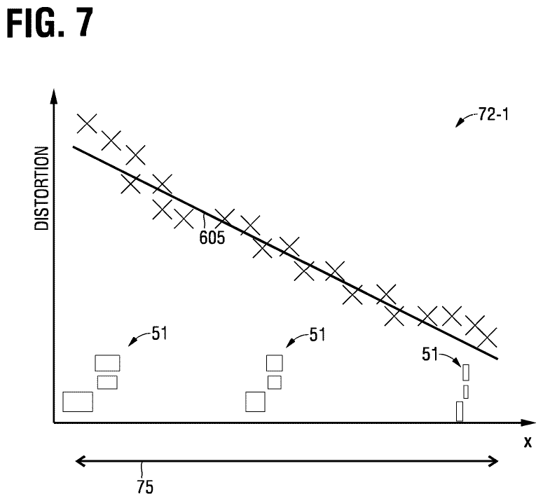

It is then possible to determine values of one or more imaging parameters for each imaging subsystem. For instance, based on such comparisons, a value of a distortion model can be determined for each imaging subsystem. Thereby, the distortion can be quantified within each FOV of each imaging subsystem. This is illustrated in FIG. 7. FIG. 7 illustrates the amount of linear distortion along the X-axis for different positions within the FOV 72-1. This is illustrated for the structure 51 (cf. FIG. 5). By choosing appropriate stage offsets between stage positions and/or structures (iterations 3036), the distortion can be sampled across the entire FOV 72-1. The distortion can be sampled at a high spatial resolution. For instance, the distortion can be determined for each pixel within the test image. This is possible where a test sample includes characteristic structures and a respective spatial resolution.

The change of the appearance of the structures 51 is detected in the test images that are compared with each other. In the illustrated example of FIG. 7, the change of appearance is in between different parts within the FOV 72-1. I.e., an intra-FOV variation is determined In other examples, the change of the appearance can be in between different FOVs (as previously discussed in connection with FIG. 6); i.e., an inter-FOV variation can be determined.

Referring again to FIG. 3: at box 3055, it is then possible to apply a correction based on the values of the one or more imaging parameters previously determined at box 3050.

Such correction can include digital post-processing corrections applied to measurement images acquired as part of the imaging process of box 3010. For instance, where values of a distortion model are determined, the respective measurement images can be undistorted by applying an inverse of the actual distortion estimated by the distortion model. For instance, where an optical transfer function is determined for different FOVs, the contrast can be digitally postprocessed so that the optical transfer functions of different FOVs match each other. For example, were different scaling factors of the FOVs are determined, different measurement images can be rescaled so that the scaling factors, after the rescaling, match.

Alternatively or additionally to such digital postprocessing correction applied to the measurement images, it is also possible to apply at least one hardware correction to the imaging hardware of the multiple imaging subsystems. For instance, voltages of electrical or magnetic optics can be adjusted.

It is, however, not required in all scenarios that a correction is applied. For instance, in some scenarios the values of the one or more imaging parameters can be compared against a predefined reference value or reference range. Based on such comparison, it can be determined whether a calibration is desired, cf. box 3060. In other words, it is possible to determine whether the values of the one or more imaging parameters as determined in box 3050 fulfill one or more desired properties. Then, depending on whether the one or more desired properties are fulfilled, a calibration process-box 3065—to calibrate the multiple imaging subsystems can be selectively triggered.

For instance, such calibration process can include moving the sample stage to a calibration position. Here, the sample may be outside of the FOVs of the multiple imaging subsystems; rather, a calibration structure can then be located in the FOVs at the calibration position. I.e., the imaging process 3010 can be interrupted to accommodate the calibration process using a-priori known reference structures. The comparison of the test images at box 3050 can be used to detect deviations from a norm; the deviations can then be further quantified using the calibration procedure of box 3065. The implementation of the calibration procedure itself is out of scope of the subject disclosure; prior art techniques can be employed.

Summarizing, above techniques have been discussed in connection with the method of FIG. 3 that enable determining values for different types of imaging parameters based on observing differences in the appearance of sample structures in test images acquired at different stage positions. Changes in the appearance of the sample structures observed responsive to a stage shift are due to variations in the imaging parameter values of the various imaging subsystems; because the structures nominally should remain the same, irrespective of the stage position. Thereby, imaging artifacts can be characterized and quantified and, if desired, corrected. These techniques are applicable to all kinds and types of imaging parameters. A specific type of imaging parameter is the distortion.

Next, a specific example implementation of box 3050 for determining values of a distortion model will be discussed. Specifically, a scenario will be discussed in which the distortion model includes a linear image shift along X direction and a further linear image shift along Y direction.

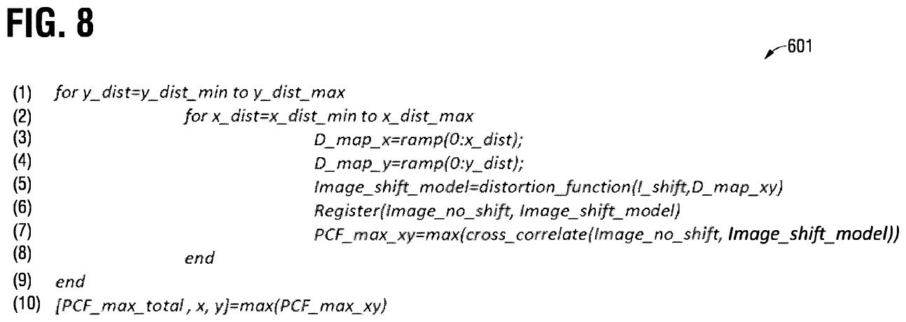

FIG. 8 shows pseudocode 601 for processes for determining the values for the X image shift and the Y image shift, respectively. These values are determined based on a first test image acquired at a first stage position and a second test image acquired at a second stage position. Both first and second test images depict the same structures. The pseudocode 601 of FIG. 8 achieves a minimization of a difference between a first test image in a distorted version of a second test image of a respective pair (i.e., the first and second test images depict the same structures and may have been registered with each other). For this, the pseudocode 609 tests multiple candidate values for a respective distortion model underlying the distorted version of the second test image.

Next, the pseudocode 601 is explained in detail, line-by-line.

In lines 1 and 9 of the pseudocode 601, as well as lines 2 and 8 of the pseudocode 601, the processes select all candidate values of linear image shifts (in respective For-loops). I.e., a predefined range of candidate values (“y_dist_min” to “y_dist_max”, as well as “x_dist_min” to “x_dist_max”) is sampled completely and sequentially and separately for X and Y direction. A linear sampling pattern from a minimum to a maximum candidate value is used. Other sampling patterns would be possible.

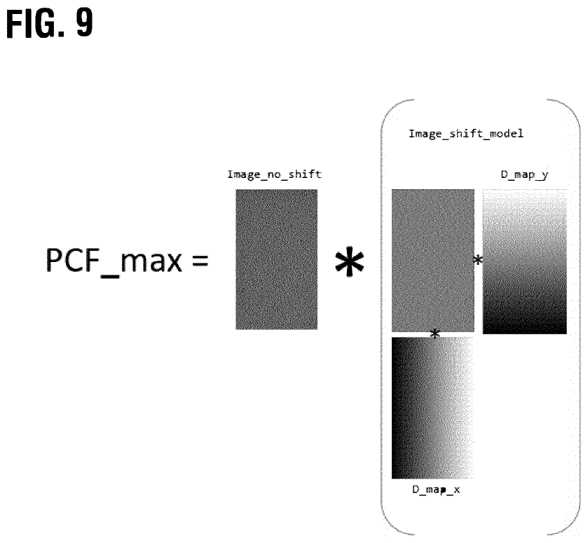

In lines 3 and 4 of the pseudocode 601, respective image shift maps are calculated, as linear ramps from zero to the respective current value. An example linear ramp 605 is shown in FIG. 7 using the full line. The maps D_map_y and D_map_x are also shown in FIG. 9.

In line 5 of the pseudocode 601 (cf. FIG. 8), a synthesized undistorted image is calculated. This is based on the second image “I_shift” acquired at the second stage position. The current x and y distortion parameters D_map_x and D_map_y are used for this calculation. This corresponds to the convolution operate in the bracket in FIG. 9.

Then, in line 6 of the pseudocode 601, the first image-acquired at the first stage position—is registered with the synthesized undistorted image (cf. box 3045 in FIG. 3). Thereby, correspondences between the same structures are found.

At line 7 of the pseudocode 601, a comparison is made between the first image and the synthesized undistorted image (cf. box 3050 in FIG. 3). This comparison is based on a correlation of these images (this is also illustrated in FIG. 9). The comparison takes into account the registration of line 6. Thus, corresponding regions of the images are correlated with each other.

In general, in some examples, the comparison includes a correlation between a first data representative of the first test image and a second data representative of the second test image, for each pair of test images.

At line 7 of the pseudocode 6, a score is determined that qualifies the correspondence between the 2 compared images. For instance, the phase correlation function can be determined. It would also be possible to determine the maximum pixel-wise match of the correlation.

At line 10, the maximum across all scores is extracted, i.e., across all candidate values; this maximum selects, from amongst all candidate values, the values to be used for the linear distortion model.

As will be appreciated, because the value of the linear shift for the X direction and the value for the linear shift in the Y direction are looped independently, the respective values are determined in independent processes. Interdependencies are not considered. This provides for a particular robust determination of the values of the respective linear shift models in X direction and Y direction, respectively.

Thereby, the difference between the synthesized undistorted image and the 1st image subject to the comparison is minimized by selection of the appropriate values for the linear distortion models along X direction and Y direction.

The pseudocode 601 of FIG. 8 tests all available candidate values for the linear distortion models along X direction and Y direction. The optimum-leading to best match between the first image and the undistorted second image—is selected. It has been found that sampling all candidate values provides a robust solution.

In other scenarios, a predefined range of candidate values can be sampled using an iterative optimization, e.g., a gradient descent iterative optimization, etc. this can reduce the computational efforts and reduce runtime.

As will be appreciated, the pseudocode 601 according to FIG. 8 uses the entirety of both test images—e.g., 3200×1500 pixels—rather than only isolated fiducials of a calibration sample. For instance, typical calibration samples would include 30×20 fiducials that can be used to determine respective values of the distortion model. The spatial resolution with which the values of the distortion model are determined based on such isolated fiducials is, accordingly, significantly lower than the spatial resolution underlying the determination using the pseudocode 601.

Furthermore, using the pseudocode 601 of FIG. 8, it is possible to determine different values of the distortion model for each imaging subsystem. Thus, each imaging subsystem can be individually characterized. Accordingly, sample imperfections, heterogeneities and image noise do not affect the analysis in the same severe manner as prior art techniques using calibration samples. Furthermore, the techniques are flexible in terms of their employed sample used to acquire the test images. As long as the sample does not significantly change between two subsequent acquisitions of test images—e.g., due to charging effects-no special provisions or specifications are used. A proprietary calibration sample or test wafer is not required.

As a further feature, a single figure of merit is determined in line 10 of the pseudocode 601. For instance, a normalized cross correlation coefficient can be calculated. The magnitude of such figure of merit is indicative of a severity of the image distortion and can be used to track the evolution of the severity of the distortion over time. This enables the stability tests.

Although the disclosure has been shown and described with respect to certain embodiments, equivalents and modifications will occur to others skilled in the art upon the reading and understanding of the specification. The present disclosure includes all such equivalents and modifications and is limited only by the scope of the appended claims.

For illustration, various examples have been explained above in connection with determining values of one or more imaging parameters of a multi-beam scanning electron microscopy system. Similarly, such techniques can be applied to other charged particle scanning imaging systems.

What is claimed is:

1. A method of monitoring a multi-beam scanning electron imaging system comprising multiple imaging subsystems having fields of view arranged in a pattern, the method comprising:
controlling a sample stage of the multi-beam scanning electron imaging system to load a sample to be imaged;
acquiring, at a first stage position, first test images of the sample stage using each of the multiple imaging subsystems;
acquiring, at a second stage position different from the first stage position, second test images using each of the multiple imaging subsystems;
for each of the multiple imaging subsystems, determining values of one or more imaging parameters characterizing the imaging subsystem based on a comparison between pairs of the first test images and the second test images depicting structures of the sample;
applying, in an imaging process to image the sample, one or more corrections based on the values of the one or more imaging parameters,
wherein:
the one or more imaging parameters comprise a distortion model of each of the multiple imaging subsystems;
for each of the pairs of the first test images and the second test images, the comparison between the pair of the first test image and the second test image comprises minimizing a difference between the first test image and a distorted version of the second test image, the minimization testing multiple candidate values for the distortion model used to calculate the distorted version of the second test image.

2. The method of claim 1, wherein the distortion model comprises a first linear image shift along a first imaging direction and a second linear image shift along a second imaging direction.

3. The method of claim 2, further comprising determining a first value of the first linear image shift and a second value the second linear image shift in independent processes.

4. The method of claim 1, wherein the distortion model consists of a first linear image shift along a first imaging direction and a second linear image shift along a second imaging direction.

5. The method of claim 1, wherein, for each of the pairs of the first test images and the second test images, the comparison between the pair of the first test image and the second test image comprises a correlation between first data representative of the respective first test image and second data representative of the respective second test image.

6. The method of claim 1, wherein at least one of the following holds:
the minimization samples a predefined range of the multiple candidate values according to a predefined sampling pattern; and
the minimization samples a predefined range of the multiple candidate values using an iterative optimization.

7. The method of claim 1, further comprising, depending on the one or more imaging parameters, determining an offset between the first stage position and the second stage position.

8. The method of claim 7, wherein:
for each of the multiple imaging subsystems, the imaging subsystem has a field of view; and
the method further comprises determining that a first imaging parameter has an offset that is less than 60% of a side length of each field of view.

9. The method of claim 8, further comprising determining that a second imaging parameter has an offset that is more than 60% of the side length of each field of view.

10. The method of claim 1, wherein, for each of the pairs of the first test images and the second test images, the comparison between the pair of the first test image and the second test image detects a change of an appearance of structures between the first test image and the second test image.

11. The method of claim 10, wherein at least one of the following holds:
the change of the appearance of the structures is in-between different parts within fields of view of the multiple imaging subsystems; and
the change of the appearance of the structures is in-between different fields of view of the multiple imaging subsystems.

12. The method of claim 1, wherein, for each of the multiple imaging subsystems, the one or more imaging parameters comprise a member selected from the group consisting of an optical transfer function of the imaging subsystem, a scale factor of the imaging subsystem, and a barrel distortion of the imaging subsystem.

13. The method of claim 1, wherein at least one of the following holds:
at least one of the one or more imaging parameters comprises values that vary within a field of view of each of the multiple imaging subsystems; and
at least one of the one or more imaging parameters comprises values that are fixed within a field of view of each of the multiple imaging subsystems and that vary between the field of view of different of the multiple imaging subsystems.

14. The method of claim 1, wherein the one or more corrections comprise a member selected from the group consisting of a digital post-processing correction applied to measurement images acquired in the imaging process and a hardware correction applied to imaging hardware of the multiple imaging subsystems.

15. The method of claim 1, further comprising:
controlling each of the multiple imaging subsystems to contemporaneously acquire a sequence of measurement images at a plurality of stage positions of the sample stage to image the sample in an imaging process; and
in interrupting the imaging process to acquire the first and second test images.

16. The method of claim 1, further comprising:
determining whether the values of the one or more imaging parameters fulfill one or more properties; and
depending on whether the values of the one or more imaging parameters fulfill the one or more properties, triggering a calibration process to calibrate the multiple imaging subsystems.

17. The method of claim 16, further comprising, in response to the calibration process being triggered, moving the sample stage to a calibration position, wherein a predefined calibration structure is located in fields of view at the calibration position.

18. The method of claim 1, wherein, for each of the pairs of the first test images and the second test images:
the method further comprises determining a registration between the pair of the first test image and the second test image; and
each comparison between the first test image and the second test image is based on the registration.

19. One or more machine-readable hardware storage devices comprising instructions that are executable by one or more processing devices to perform operations comprising the method of claim 1.

20. A system comprising:
one or more processing devices; and
one or more machine-readable hardware storage devices comprising instructions that are executable by the one or more processing devices to perform operations comprising the method of claim 1.
